(19) United States
(12) Patent Application Publication
(10) Pub. No.: US 2014/0327056 A1
(43) Pub. Date: Nov. 6, 2014

(54) SEMICONDUCTOR DEVICE HAVING CONTACT PLUG AND METHOD OF MANUFACTURING THE SAME

(71) Applicant: Samsung Electronics Co., Ltd., Suwon-si (KR)

(72) Inventors: Jung-hwan Park, Seoul (KR); Je-min Park, Suwon-si (KR); Tai-heui Cho, Suwon-si (KR)

(73) Assignee: Samsung Electronics Co., Ltd., Suwon-si (KR)

(21) Appl. No.: 14/261,822

(22) Filed: Apr. 25, 2014

(30) Foreign Application Priority Data
May 1, 2013 (KR) 10-2013-0049049

(51) Int. Cl. H01L 29/78

(52) U.S. Cl. CPC H01L 29/78
USPC 257/288

(57) ABSTRACT

A semiconductor device having a contact plug is manufactured. The semiconductor device includes a substrate having a cell array region and a peripheral circuit region, a gate electrode on the substrate, and an interlayer dielectric layer on the substrate. The interlayer dielectric layer has an upper surface having a first height.

The device further comprises a contact hole extending through the interlayer dielectric layer and a contact plug having an upper surface and electrically connecting to the substrate in the contact hole. The upper surface of the contact plug has a second height lower than the first height. A spacer is on the sidewall of the contact hole. A first conductive line is on the spacer and the upper surface of the contact plug.

### CROSS-REFERENCE TO RELATED APPLICATIONS

This U.S. non-provisional patent application claims priority under 35 U.S.C. §119 to Korean Patent Application No. 10-2013-0049049, filed on May 1, 2013, in the Korean Intellectual Property Office (KIPO), the contents of which are herein incorporated by reference in their entirety.

### TECHNICAL FIELD

The present inventive concepts herein relate to a semiconductor device having a contact plug and a method of manufacturing the same.

### BACKGROUND

Due to the growing demands for miniaturization of a semiconductor device, conductive lines and contact plugs formed in the semiconductor device have been reduced. However, such reductions in size may result in issues related to electrical connections, for example, misalignments between the conductive lines and the contact plugs, and, more specifically, a possible undercut phenomenon where the conductive lines do not cover the upper surface of the contact plugs due to a misalignment between them, which can decrease the performance and reliability of the semiconductor device.

### SUMMARY

The present inventive concepts provide a semiconductor device having a contact plug and a method of manufacturing the same. The contact plug may be formed in a contact hole having a sidewall. A spacer may be formed on the sidewall of the contact hole.

In accordance with one aspect of the inventive concepts, a semiconductor device is provided including a substrate having a cell array region and a peripheral circuit region; a gate electrode on the substrate; an interlayer dielectric layer adjacent to the gate electrode on the substrate, the interlayer dielectric layer having an upper surface having a first height; a contact hole extending through the interlayer dielectric layer to expose a portion of the substrate; a contact plug having an upper surface and electrically communicating with the substrate in the contact hole, the upper surface of the contact plug having a center portion, edge portion, and a second height lower than the first height; a spacer on the sidewall of the contact hole, the spacer directly abutting the edge portion of the upper surface of the contact plug;

and a first conductive line on the spacer and the center portion of the upper surface of the contact plug, the first conductive line electrically communicating with the contact plug.

In some embodiments, the gate electrode is positioned at the peripheral circuit region.

In some embodiments, the gate electrode includes at least one of tungsten (W), tungsten silicide (WSix), and titanium silicon nitride (TiSiN) or a combination thereof.

In some embodiments, the semiconductor device further comprises a gate hard mask pattern on the gate electrode; and a gate dielectric layer between the gate electrode and the substrate.

In some embodiments, the semiconductor device further comprises a portion of a second conductive line positioned on the gate hard mask pattern.

In some embodiments, the semiconductor device further comprises a second conductive line on the upper surface of the interlayer dielectric layer, the second conductive line adjacent to the first conductive line.

In some embodiments, the first and second conductive lines are portions of bit lines.

In some embodiments, the first and second conductive lines include tungsten (W).

In some embodiments, the semiconductor device further comprises a first barrier metal layer between the contact plug and the substrate.

In some embodiments, the first barrier metal layer includes at least one of titanium (Ti), titanium nitride (TiN), and titanium silicon nitride (TiSiN) or a combination thereof.

In some embodiments, the semiconductor device further comprises a second barrier metal layer between the contact plug and the first conductive line.

In some embodiments, the second barrier metal layer includes at least one of titanium (Ti), titanium nitride (TiN), and titanium silicon nitride (TiSiN) or a combination thereof.

In some embodiments, the spacer includes at least one of silicon nitride (SiN), silicon oxynitride (SiON), and silicon dioxide (SiO₂) or a combination thereof.

In some embodiments, the spacer has two portions, the two portions comprising: a first portion adjacent to the upper surface of the interlayer dielectric layer, the first portion having a first width; and a second portion physically contacting to the contact plug, the second portion having a second width smaller than the first width.

In some embodiments, the center portion of the upper surface of the contact plug has a third width and the bottom of the contact hole has a fourth width greater than or equal to the third width.

In accordance with another aspect of the inventive concepts, provided is a semiconductor device, comprising: a substrate having a cell array region and a peripheral circuit region; a plurality of bit lines disposed on the substrate in the cell array region; a gate electrode having a sidewall on the substrate in the peripheral circuit region; a gate spacer on the sidewall of the gate electrode; an interlayer dielectric layer adjacent to the gate electrode on the substrate, the interlayer dielectric layer having an upper surface having a first height; a contact hole extending through the interlayer dielectric layer to expose a portion of the substrate, the contact hole adjacent to the gate spacer; a contact plug having an upper surface and electrically communicating with the substrate in the contact hole, the upper surface of the contact plug having a center portion, an edge portion, and a second height lower than the first height; a spacer on the sidewall of the contact hole, the spacer directly abutting the edge portion of the upper surface of the contact plug; a first conductive line on the spacer and the center portion of the upper surface of the contact plug, the first conductive line electrically communicating with the contact plug; and a second conductive line on the upper surface of the interlayer dielectric layer, the second conductive line adjacent to the first conductive line.

In accordance with another aspect of the inventive concepts, provided is method of manufacturing a semiconductor device, the method comprising: providing a substrate having a cell array region and a peripheral circuit region; forming a gate electrode on the substrate; forming an interlayer dielectric layer adjacent to the gate electrode on the substrate, the interlayer dielectric layer having an upper surface having a first height; forming a contact hole extending through the interlayer dielectric layer to expose a portion of the substrate; forming a contact plug having an upper surface and electrically communicating with the substrate in the contact hole, the upper surface of the contact plug having a second height lower than the first height; forming a spacer on the sidewall of the contact hole, the spacer directly abutting the edge portion of the upper surface of the contact plug; forming a first conductive line on the spacer and the center portion of the upper surface of the contact plug, the first conductive line electrically communicating with the contact plug; and forming a second conductive line on the upper surface of the interlayer dielectric layer, the second conductive line adjacent to the first conductive line.

In some embodiments, the gate electrode is formed in the peripheral circuit region.

In some embodiments, wherein the spacer has two portions, the two portions comprising: a first portion adjacent to the upper surface of the interlayer dielectric layer, the first portion having a first width; and a second portion directly abutting the contact plug, the second portion having a second width smaller than the first width.

In accordance with another aspect of the inventive concepts, provided is a semiconductor device, comprising: a substrate having a cell array region and a peripheral circuit region; an interlayer dielectric layer on the substrate; a contact hole extending through the interlayer dielectric layer to expose a portion of the substrate; a contact plug in the contact hole, an upper surface of the contact plug having a center portion and edge portion, the upper surface of the contact plug lower than an upper surface of the interlayer dielectric layer, an exposed portion of a sidewall of the contact hole extending between the upper surface of the interlayer dielectric layer and the edge portion of the upper surface of the contact plug; a spacer on the exposed portion of the sidewall of the contact hole; and a conductive line on the spacer and the center portion of the upper surface of the contact plug.

### BRIEF DESCRIPTION OF THE DRAWINGS

The foregoing and other features and advantages of the inventive concepts will be apparent from the more particular description of embodiments of the inventive concepts, as illustrated in the accompanying drawings in which like reference characters refer to the same parts throughout the different views. The drawings are not necessarily to scale, emphasis instead being placed upon illustrating the principles of the inventive concepts.

FIGS. 1 through 20 are cross-sectional views illustrating a method of manufacturing a semiconductor device, according to an embodiment of the inventive concepts.

FIGS. 11 through 13 are cross-sectional views illustrating a method of manufacturing a semiconductor device according to another embodiment of the inventive concepts.

FIG. 14 is a layout of a cell array region illustrating a method of manufacturing a semiconductor device according to another embodiment of the inventive concepts.

FIGS. 15a through 22d are cross-sectional views illustrating a method of manufacturing a semiconductor device according to another embodiment of the inventive concepts.

FIG. 23 is a diagram of a system according to an embodiment of the inventive concepts.

FIG. 24 is a memory card including a semiconductor device according to an embodiment of the inventive concepts.

### DETAILED DESCRIPTION OF EMBODIMENTS

Exemplary embodiments of the inventive concept will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the inventive concepts to those skilled in the art.

It will also be understood that when a layer or element is referred to as being “on” another layer or substrate, it can be directly on the other layer or substrate, or intervening layers may also be present. Further, it will be understood that when a layer is referred to as being “under” another layer, it can be directly under or one or more intervening layers may also be present. In addition, it will also be understood that when a layer is referred to as being “between” two layers, it can be the only layer between the two layers, or one or more intervening layers may also be present.

In the drawing figures, the dimensions of layers and regions may be exaggerated for clarity of illustration. Like reference numerals refer to like elements throughout. The same reference numbers indicate the same components throughout the specification.

Spatially relative terms, such as “beneath,” “below,” “lower,” “above,” “upper” and the like, may be used herein for ease of description to describe the relationship of one element or feature to another element(s) or feature(s), as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The use of the terms “a” and “an” and “the” and similar referents in the context of describing embodiments (especially in the context of the following claims) are to be construed to cover both the singular and the plural, unless otherwise indicated herein or clearly contradicted by context. The terms “comprising,” “having,” “including,” and “containing” are to be construed as open-ended terms (i.e., meaning “including, but not limited to”) unless otherwise noted.

Unless defined otherwise, all technical and scientific terms used herein have the same meaning as commonly understood by one of ordinary skill in the art. It is noted that the use of any and all examples, or exemplary terms provided herein is intended merely to better illuminate the exemplary embodiments and is not a limitation on the scope of the inventive concepts unless otherwise specified.

Embodiments will be described with reference to perspective views, cross-sectional views, and/or plan views. The profile of an exemplary view may be modified according to, e.g., manufacturing techniques and/or allowances. Accordingly, the exemplary embodiments are not intended to limit the scope, but cover all changes and modifications that can be caused due to, e.g., a change in manufacturing process. Thus, regions shown in the drawings are illustrated in schematic form and the shapes of the region are presented simply by way of illustration and not as a limitation.

In brief overview, a semiconductor device is provided that can prevent or mitigate the risk of the occurrence of an undercut at a contact plug even if a misalignment occurs during formation of a conductive line on the contact plug.

Hereinafter, example embodiments of the inventive concepts will be described in detail with reference to the accompanying drawings.

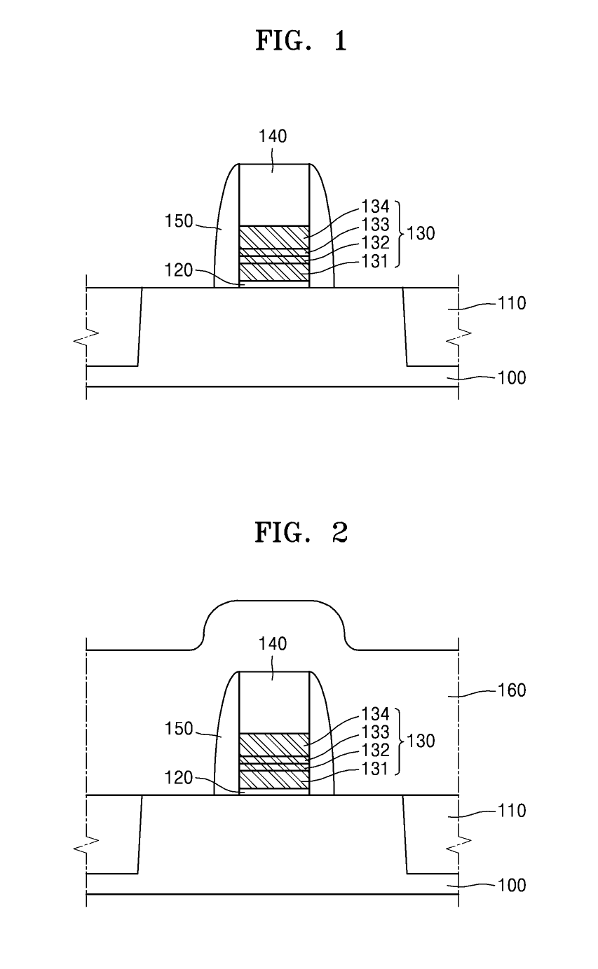

FIGS. 1 through 10 are cross-sectional views illustrating a method of manufacturing a semiconductor device according to an embodiment of the inventive concepts.

Referring to FIG. 1, a substrate 100 having a cell array region and a peripheral circuit region may be provided. The substrate 100 may comprise a rigid substrate, such as a bulk silicon substrate, a silicon-on-insulator (SOI) substrate, a germanium substrate, a silicon germanium substrate, an indium antimonide substrate, a lead telluride substrate, an indium arsenide substrate, an indium phosphorus substrate, a gallium arsenide substrate, and/or an antimony gallium substrate.

The substrate 100 may include a device isolation region 110 that may be formed by a shallow-trench-isolation (STI) process. The device isolation region 110 may include a silicon oxide layer formed by a high-density-plasma (HDP) process or a flowable-chemical-vapor-deposition (FCVD) process.

A gate electrode 130 having a sidewall may be formed on the substrate. The gate electrode may include, but not be limited to, a polysilicon layer 131, a tungsten layer 132, a tungsten silicide layer 133, and a titanium silicon nitride layer 134, or a combination thereof. The gate electrode 130 may be formed on at least one of the cell array region or the peripheral circuit region.

A gate dielectric layer 120 may be formed between the gate electrode 130 and the substrate 100. The gate dielectric layer 120 may include silicon oxide and/or a high-k material, e.g., hafnium (Hf) or zirconium (Zr). The silicon oxide layer may comprise a silicon dioxide (SiO₂) layer.

A gate hard mask pattern 140 having an upper surface may be formed on the gate electrode 130. A gate spacer 150 may be formed on the side wall of the gate electrode 130. The gate hard mask pattern 140 and the gate spacer 150 may include, but not be limited to, at least one of silicon nitride (SiN), silicon oxynitride (SiON), and/or silicon oxide (SiO₂) or a combination thereof.

Referring to FIG. 2, an interlayer dielectric layer 160, which has an upper surface, may be formed on the substrate 100 and the gate hard mask pattern 140. The interlayer dielectric layer 160 may include a silicon oxide layer formed by a high-density-plasma (HDP) process or a flowable-chemical-vapor-deposition (FCVD) process. The upper surface of the interlayer dielectric layer 160 may have a first height.

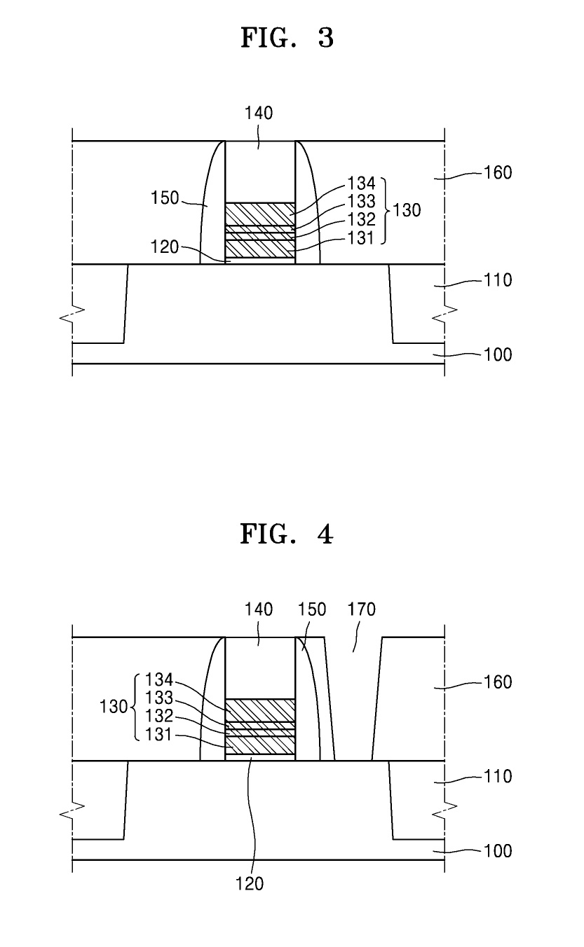

Referring to FIG. 3, the interlayer dielectric layer 160 may be planarized by an etch-back process or a chemical-mechanical-polishing (CMP) process to expose an upper surface of the gate hard mask pattern 140.

Referring to FIG. 4, a contact hole 170 is formed that extends through the interlayer dielectric layer 160 and exposes an upper surface of the substrate 100 adjacent the gate electrode 130. The contact hole 170 may have a sidewall and a bottom.

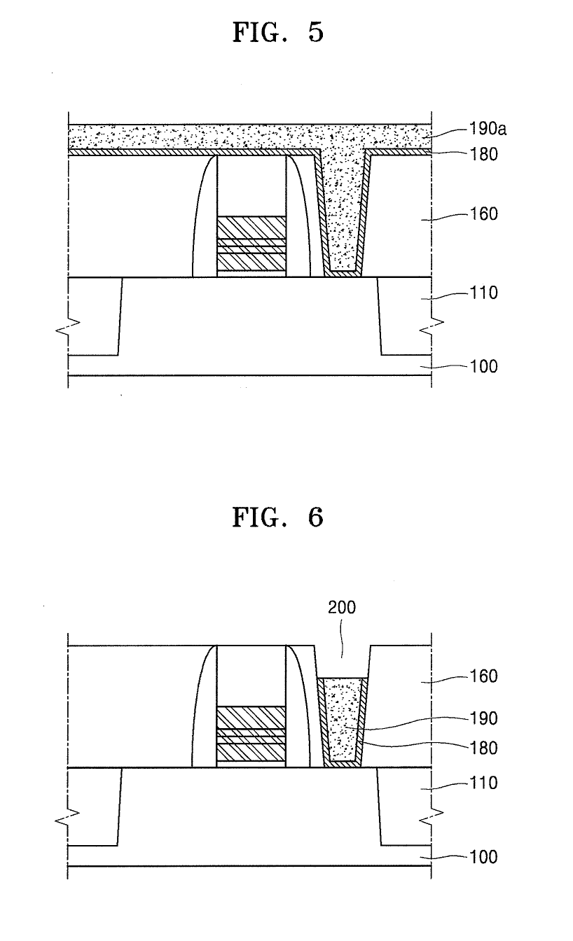

Referring to FIG. 5, a first barrier metal layer 180 may be formed on the sidewall and the bottom of the contact hole 170. The first barrier metal layer 180 may include, but not be limited to titanium (Ti), titanium nitride (TiN), and/or titanium silicon nitride (TiSiN) or a combination thereof. A contact plug material layer 190a may be formed on the first barrier metal layer 180 and may include tungsten (W). The contact plug material layer 190a may at least substantially fill or completely the contact hole 170. The first barrier metal layer 180 may extend to at least a portion of the upper surface of the interlayer dielectric layer 160.

Referring to FIG. 6, the first barrier metal layer 180 and the contact plug material layer 190a may be planarized by an etch-back process or a chemical-mechanical-polishing (CMP) process to expose the upper surface of the interlayer dielectric layer 160. A contact plug 190, which has an the upper surface, may be formed in the contact hole 170 by recessing the first barrier metal layer 180 and the contact plug material layer 190a using an etch-back process. The upper surface of the contact plug 190 may have a center portion, an edge portion, and a second height lower than the first height. A recess region 200 is formed in the interlayer dielectric layer 160 to have a depth, a sidewall, and a bottom. The recess region 200 may be formed on the contact plug 190. The recess region 200 may have a depth. The depth may be approximately 50 nm.

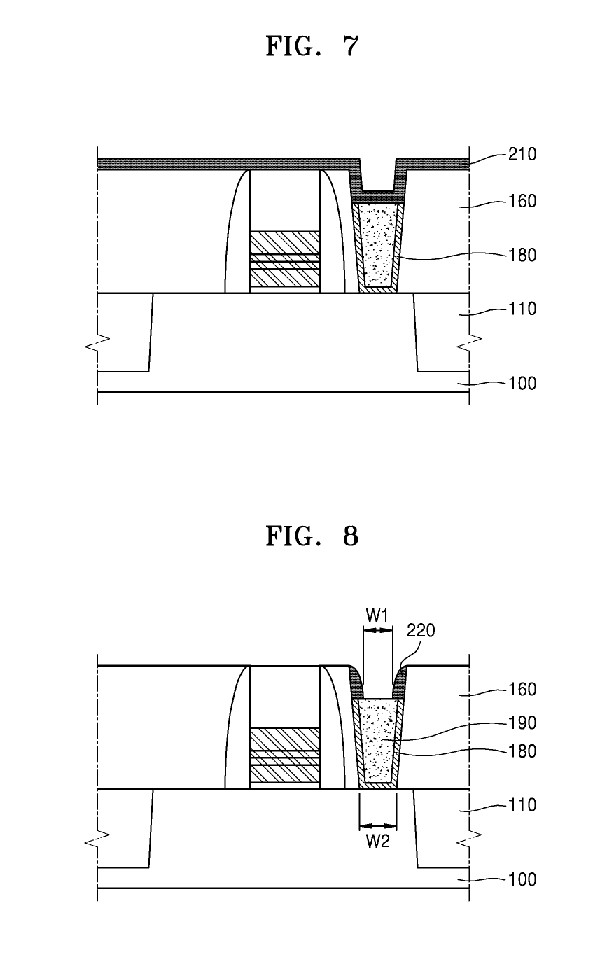

Referring to FIG. 7, a spacer material layer 210 may be formed on the sidewall of the recess region 200, more specifically, the top surface of the contact plug 190 and ends of the first barrier material layer 180 at the bottom of the recess region 200. The spacer material layer 210 may be extended on the upper surface of the interlayer dielectric layer 160. The spacer material layer 210 may include but not be limited to silicon nitride (SiN), silicon oxynitride (SiON), and/or silicon dioxide (SiO₂), or a combination thereof.

Referring to FIG. 8, one or more spacers 220 may be formed on the sidewall of the recess region 200 by applying an etch-back process. During the etch-back process, the spacer material layer 210 shown at FIG. 7 may be etched to expose the upper surface of the interlayer dielectric layer 160 and the center portion of the contact plug 190. Here, a first width (W1) which is a width of the exposed upper surface of the contact plug 190 may be smaller than or equal to a second width (W2) which is a width of the bottom of the contact hole 170.

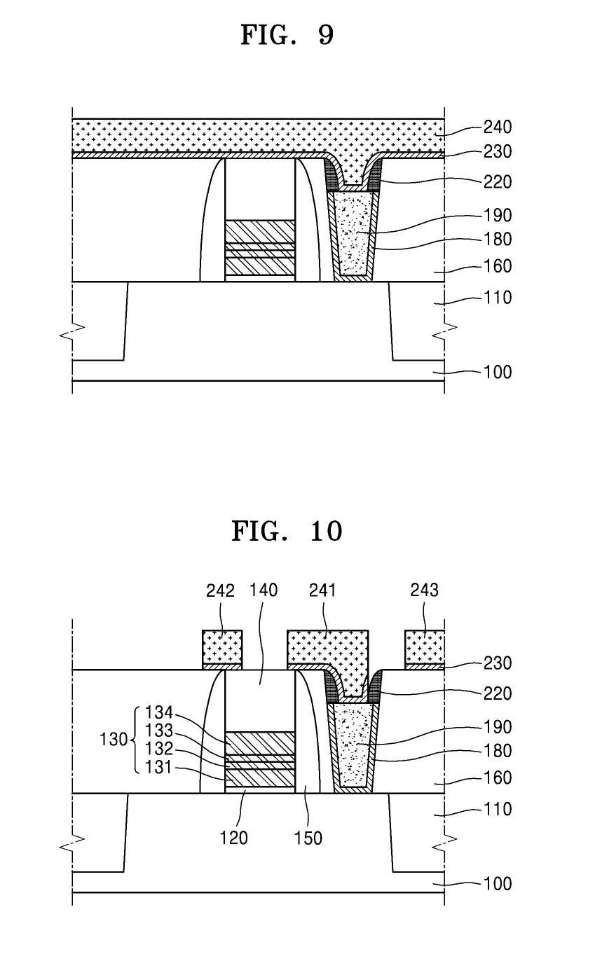

Referring to FIG. 9, a second barrier metal layer 230 and a conductive material layer 240 may be formed on the dielectric layer 160 and in the recess region 200 in the interlayer dielectric layer 160 above the contact plug 190. The second barrier metal layer 230 may include but not be limited to titanium (Ti), titanium nitride (TiN), and titanium silicon nitride (TiSiN). The conductive material layer 240 may include tungsten (W), or a combination thereof.

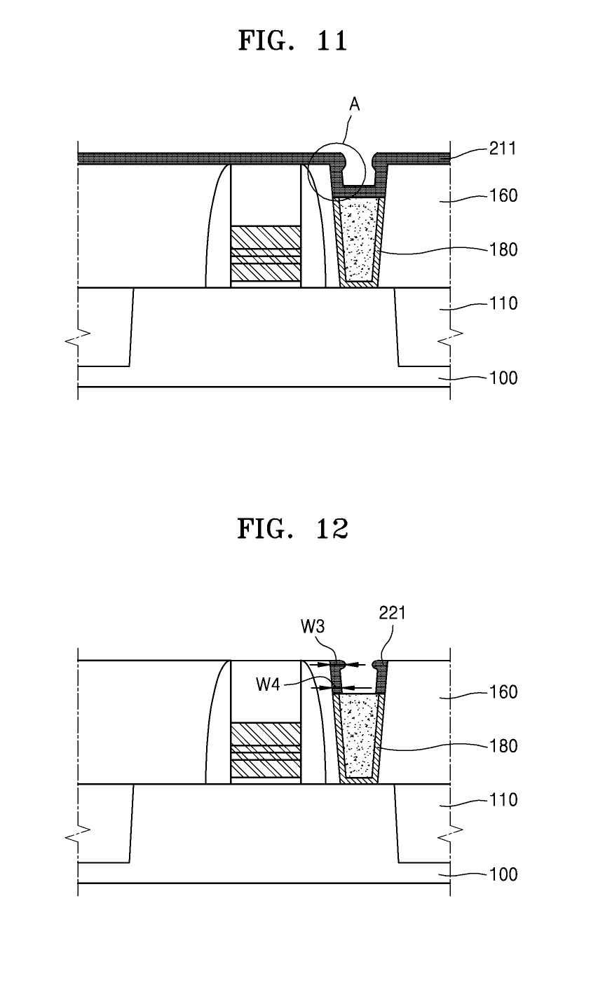

Referring to FIG. 10, first, second and third conductive lines 241, 242, and 243 may be formed on the interlayer dielectric layer 160 by applying a lithography process and a dry etching process. The first, second and third conductive lines 241, 242, and 243 may be part of a plurality of bit lines respectively. At least a portion of the first conductive line 241 may be formed on the spacer 220 and the center portion of the upper surface of the contact plug 190. At least a portion of the second conductive line 242 may be formed on the upper surface of the gate hard mask pattern 140.

FIGS. 1 through 6 and FIGS. 11 through 13 are cross-sectional views illustrating a method of manufacturing a semiconductor device according to another example embodiment of the inventive concepts. The method will be explained only differentiation with respect to the previous embodiment, i.e., FIGS. 1 through 6, a description of which will not be repeated due to brevity.

Referring to FIG. 11, which can follow FIG. 6 in the method, a spacer material layer 211 may be formed on the sidewall and the bottom of the recess region 200 and the interlayer dielectric layer 160. The spacer material layer 211 may include but not be limited to silicon nitride (SiN), silicon oxynitride (SiON), and silicon dioxide (SiO₂), or a combination thereof. A spacer material layer 211 may be formed using a non-conformal deposition process by increasing an injection amount of a silicon source gas, e.g., silane (SiH₄), as compared to a conformal deposition process. As the result, the spacer material layer 211 may have a thicker portion that is adjacent to the upper sidewall of the recess region 200 as shown by the protrusion identified by circle A.

Referring to FIG. 12, a spacer 221 may be formed on at least one sidewall of the recess region 200 using an etch-back process. During an etch-back process, the spacer material layer 211 may be etched to expose the upper surface of the interlayer dielectric layer 160 and the center portion of the contact plug 190. The spacer 221 may have two portions, in particular, a first portion, which has a first width (W3), being adjacent to the upper sidewall of the recess region 200 and a second portion, which has a second width (W4) smaller than the first width (W3), physically contacting to the contact plug 190.

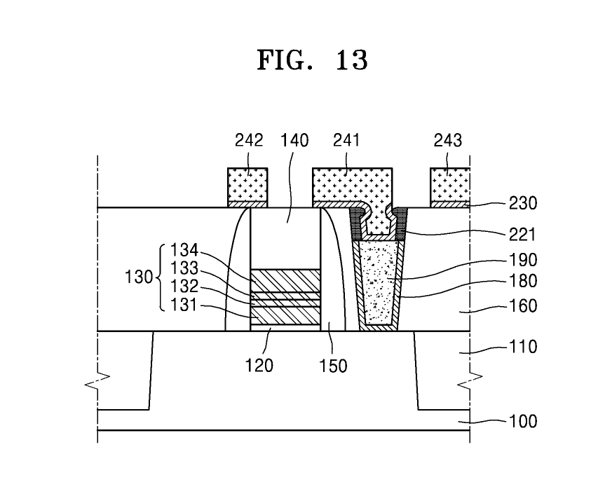

Referring to FIG. 13, first, second and third conductive lines 241, 242, and 243 may be formed on the interlayer dielectric layer 160 by applying a lithography process and a dry etching process. A second barrier metal layer 230 may be formed on the dielectric layer 160 before forming the first, second and third conductive lines 241, 242, and 243. The second barrier metal layer 230 may include but not be limited to titanium (Ti), titanium nitride (TiN), and titanium silicon nitride (TiSiN), or a combination thereof. The first, second and third conductive lines 241, 242, and 243) may include tungsten (W) and comprise at least a portion of one or more bit lines. At least a portion of the first conductive line 241 may be formed on the spacer 220 and the center portion of the upper surface of the contact plug 190. At least a portion of the second conductive line 242 may be formed on the upper surface of the gate hard mask pattern 140.

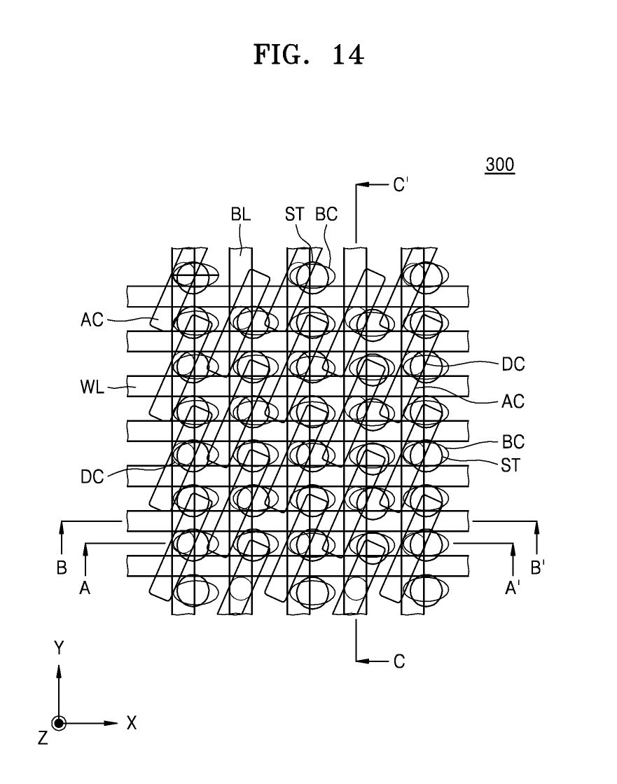

FIG. 14 is a schematic planar layout of a cell array region illustrating a semiconductor device 300 according to another embodiment of the inventive concepts. A peripheral circuit region may be formed in a periphery adjacent a cell array region. The cell array region may comprise a plurality of a unit cell region that may have a size of 6 F². Here, 1 F refers to a minimum lithographic feature size.

As disclosed herein with respect to embodiments of the inventive concepts, the gate electrode 130 may be formed in a cell array region or a peripheral circuit region. However, in an embodiment illustrated at FIG. 14, the gate electrode 130 is formed in the peripheral circuit region.

Referring to FIG. 14, a semiconductor device 300 may comprise a plurality of active regions (AC) rotated from the X-axis and Y-axis to a certain angle. A plurality of word lines (WL) may extend along a first direction (X-axis) and cross the active regions (AC) to a first direction. The word lines (WL) are parallel with each other. A plurality of bit lines (BL) may perpendicularly cross the plurality of word lines (WL) and extend along a second direction (Y-axis). The bit lines (BL) are likewise parallel with each other.

The plurality of bit lines (BL) having an upper surface may be connected to the plurality of active regions (AC) through a plurality of direct contacts (DC). If the semiconductor device has the size of 6 F² for the unit cell region, the bit lines (BL) may be disposed in parallel and have a pitch of 3 F. The word lines (WL) may be disposed in parallel and have a pitch of 2 F.

A plurality of buried contacts (BC) having an upper surface may be formed between the adjacent bit lines (BL) and are electrically connected to the plurality of active regions (AC). The upper surface of the plurality of buried contacts (BC) may have a same height as an upper surface of the plurality of bit lines (BL). The upper surfaces of the plurality of buried contacts (BC) may be electrically connected to a plurality of lower electrodes (ST) of capacitors.

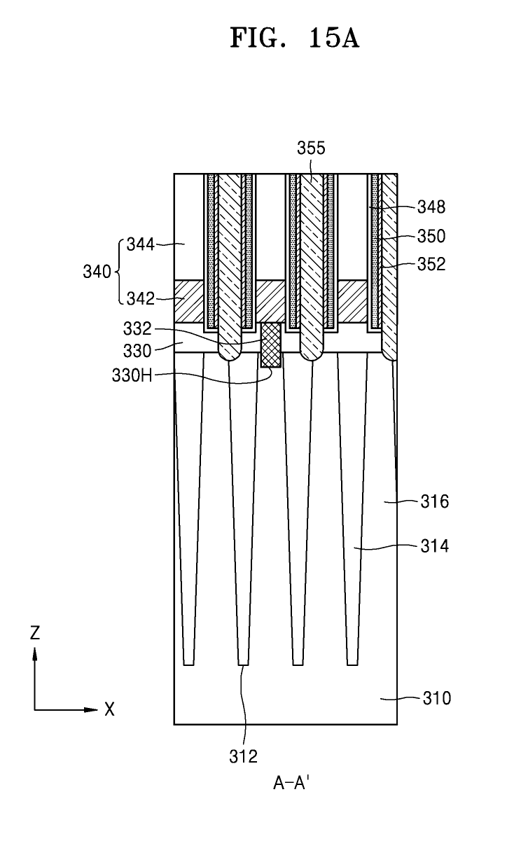

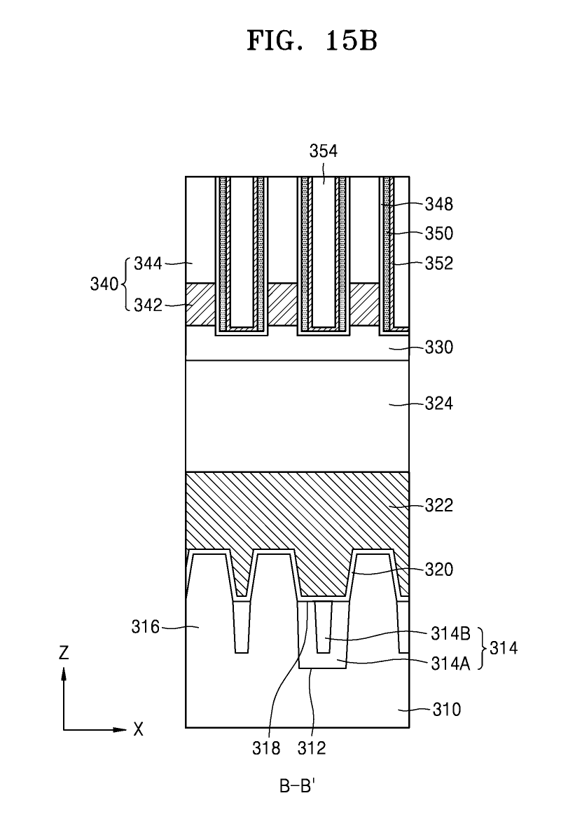

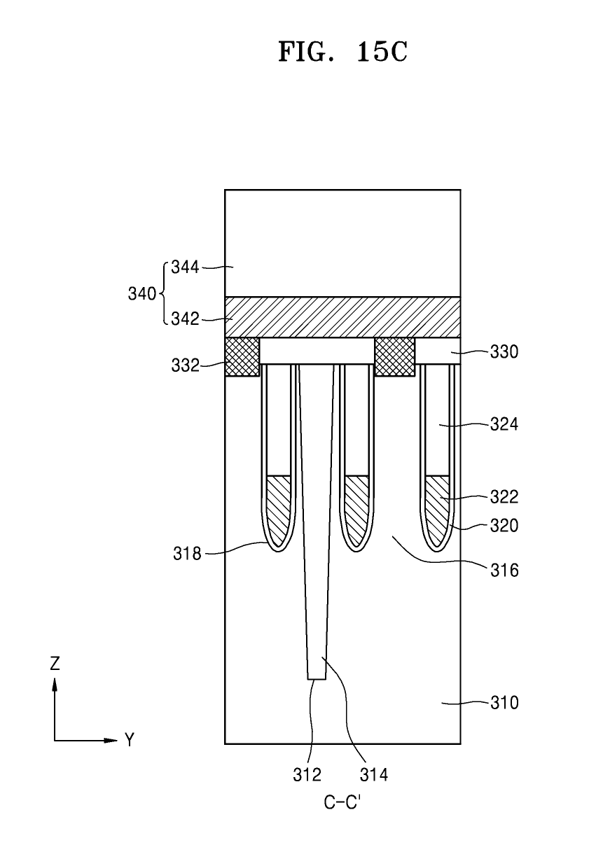

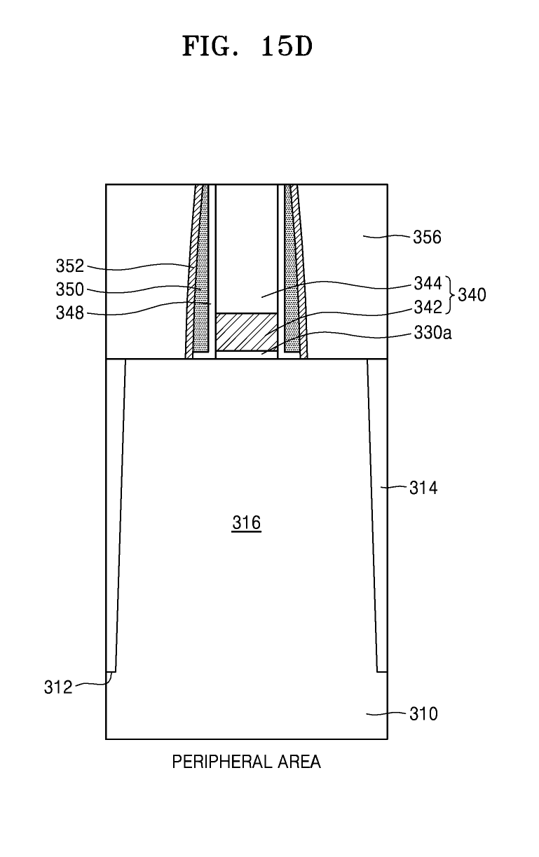

FIGS. 15a through 22d are cross-sectional views illustrating a method of manufacturing a semiconductor device according to another embodiment of the inventive concepts.

FIGS. 15a, 18a, 19a, 20a, 21a, and 22a are cross-sectional views along the line A-A′ in FIG. 14. FIGS. 15b, 18b, 19b, 20b, 21b, and 22b are cross-sectional views along the line B-B′ in FIG. 14. FIGS. 15c, 18c, 19c, 20c, 21c, and 22c are cross-sectional views along the line C-C′ in FIG. 14. FIGS. 15d, 16, 17, 18d, 19d, 20d, 21d, and 22d are cross-sectional views of a peripheral circuit region, in accordance with some embodiments.

Referring to FIGS. 15a through 15d, a device isolation trench 312 may be formed in a substrate 310 having an upper surface. A device isolation layer 314 may be formed in the device isolation trench 312. A plurality of the active regions 316 that may be defined by the device isolation layer 314 may be formed on the substrate 310. The plurality of active regions 316 may have an island shape having a major axis and a minor axis. The substrate 310 may comprise a rigid substrate, such as a bulk silicon substrate, a silicon-on-insulator (SOI) substrate, a germanium substrate, a silicon germanium substrate, an indium antimonide substrate, a lead telluride substrate, an indium arsenide substrate, an indium phosphorus substrate, a gallium arsenide substrate, or an antimony gallium substrate.

As shown in FIG. 15b, the device isolation layer 314 may comprise a first dielectric layer 314A and a second dielectric layer 314B. The first and second dielectric layers 314A and 314B may be formed of different materials, i.e., the first dielectric layer 314A may be formed of a silicon oxide layer and the second dielectric layer 314B may be formed of a silicon nitride layer. In another embodiment, the device isolation layer 314 may be formed of a single layer having a single material or a multiple layer comprising at least three layers having different materials.

A plurality of word line trenches 318 may be formed on the device isolation layer 314. The plurality of word line trenches 318 may cross the plurality of the active regions 316 in parallel. A gate dielectric layer 320 and a plurality of word lines 322 may be formed in the plurality of word line trenches 318. A plurality of buried dielectric layers 324 may be formed on the word lines 322. A source and drain region (not shown in FIG. 15b) may be formed in the substrate 310 at both sides of the plurality of word lines 322 by injecting an impurity into the substrate 310 using an ion implantation process. The source and drain region may be formed prior to forming the word lines 322.

A lower surface of the word lines 322 may have a lower height than the upper surface of the substrate 310. The word lines 322 may include but not be limited to titanium (Ti), titanium nitride (TiN), tantalum (Ta), tantalum nitride (TaN), tungsten (W), tungsten nitride (WN), titanium silicon nitride (TiSiN), and tungsten silicon nitride (WSiN), or a combination thereof. The gate dielectric layer 320 may include but not be limited to silicon oxide, silicon nitride, silicon oxynitride, ONO (oxide/nitride/oxide), and a high-k dielectric material or a combination thereof. The buried dielectric layers 324 may include but not be limited to a silicon oxide layer, a silicon nitride layer, and a silicon oxynitride layer or a combination thereof.

As shown in FIGS. 15a and 15c, the buried dielectric layers 324 may have an upper surface having the same height as the upper surface of the substrate 310. A dielectric layer pattern 330 may be formed on the substrate 310. The dielectric layer pattern 330 may include silicon oxide and be formed of TEOS (tetra-ethyl-ortho-silicate), HDP (high-density-plasma), or BPSG (boron-phosphorus-silicate-glass). The dielectric layer pattern 330 may be formed of the same material as the gate dielectric layer 320. The dielectric layer pattern 330 may have a plurality of openings 330H exposing a portion of the source region. A plurality of direct contacts 332 which are electrically connected to the plurality of active regions 316 may be formed in the openings 330H. The active regions 316 may be formed by filling the openings 330H with a conductive material.

A plurality of bit line structures 340, in parallel with each other, may be formed on the dielectric layer pattern 330 and the direct contacts 332. The bit line structures 340 may comprise the plurality of bit lines 342 and a plurality of dielectric capping lines 344 covering the plurality of bit lines 342. The plurality of bit lines 342 may be electrically connected to the direct contacts 332.

The plurality of bit lines 342 may include but not be limited to doped semiconductor material, tungsten, conductive metal nitride, and metal silicide or a combination thereof. In another embodiment, the plurality of bit lines 342 may include a first metal silicide layer, a conductive barrier layer, a second metal silicide layer, a metal layer, and/or metal nitride layer. The dielectric capping lines 344 may comprise silicon nitride.

Insulating spacers 348, 350, and 352 may be formed on the sidewalls of the bit line structures 340. The insulating spacers 348, 350, and 352 may be formed of silicon oxide, silicon nitride, and/or silicon oxynitride. The Insulating spacers 348, 350, and 352 may be formed of a same or similar material.

Referring to FIG. 15b, a plurality of insulating material layers 354 at least substantially fill a plurality of gaps between the plurality of bit line structures 340. The insulating material layers 354 may be formed at the outer insulating spacer 352. The insulating material layers 354 may be formed of silicon oxide or silicon nitride. The upper surfaces of the insulating material layers 354 may be planarized by a CMP process and have same height with the upper surface of the plurality of the bit line structures 340. A plurality of buried contact holes may be formed between the plurality of bit line structures 340 by removing the plurality of insulating material layers 354. Referring again to FIG. 15a, the buried contact holes may expose a portion of the active regions (AC) and be filled with a conductive material 355 that may comprise a plurality of buried contacts (BC). The conductive material 355 may be formed of doped polysilicon, metal, metal silicide, and/or conductive metal nitride. A barrier metal layer (not shown in FIG. 15a) may be formed in the buried contact holes before forming the conductive material 355. The barrier metal layer may include titanium (Ti) and/or titanium nitride (TiN).

Referring to FIG. 15d, a gate structure 340 may be formed on the substrate 316 in the peripheral circuit region. The gate structure 340 may include a gate electrode 342 and a gate hard mask pattern 344. A gate dielectric layer 330a may be formed on the substrate 310 before forming the gate structure 340. The gate electrode 342 may have the same or similar material as that of the bit lines 342 formed in the cell array region. The gate electrode 342 may include polysilicon, tungsten, tungsten silicide, and/or silicon titanium nitride. The gate dielectric layer 330a may include silicon oxide, silicon nitride, silicon oxynitride, ONO (oxide/nitride/oxide), and/or high-k dielectric material.

A gate spacer may be formed on the sidewall of the gate structure 340. The gate spacer may be formed of a same or similar material as that of the insulating spacers 348, 350, and 352. An interlayer dielectric layer 356 having an upper surface may be formed on the substrate 310 and the gate spacer.

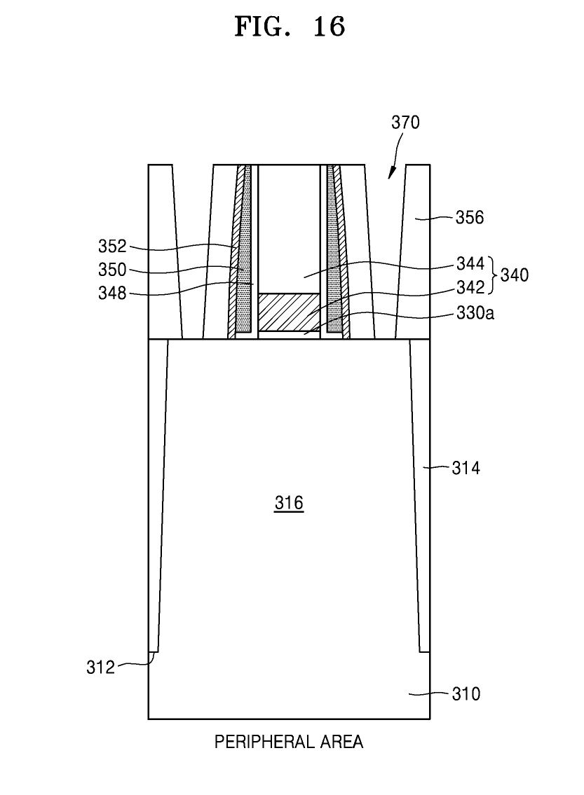

Referring to FIG. 16, a photoresist pattern may be formed on the interlayer dielectric layer 356 to form a plurality of contact holes 370 by applying a photolithography technique or the like. The plurality of contact holes 370 may be formed by etching the interlayer dielectric layer 356 to expose an upper surface of the active region 316 using the photoresist as an etching mask. The contact holes 370 may each have a sidewall and a bottom. The photoresist pattern may be removed after forming the plurality of contact holes 370.

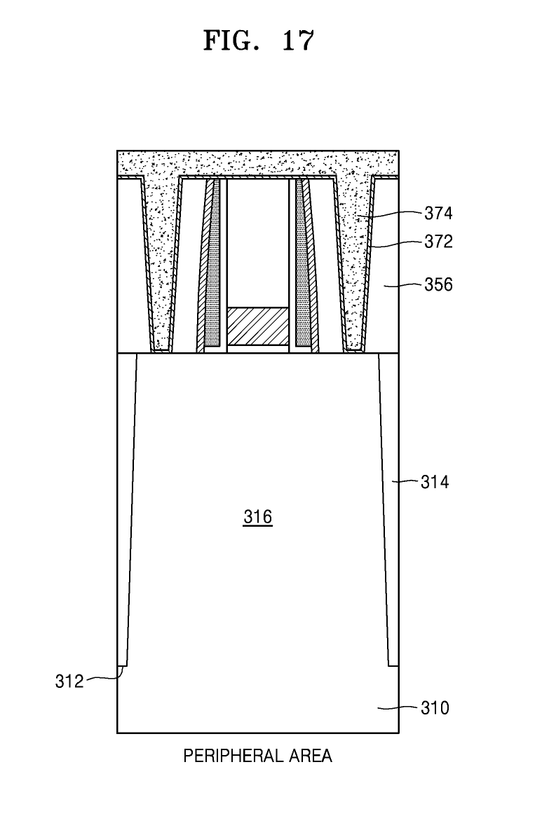

Referring to FIG. 17, a first barrier metal layer 372 and a contact plug material layer 374 may be formed in the plurality of contact holes 370. The first barrier metal layer 372 may include titanium, titanium nitride, and/or titanium silicon nitride. The contact plug material layer 374 may include tungsten.

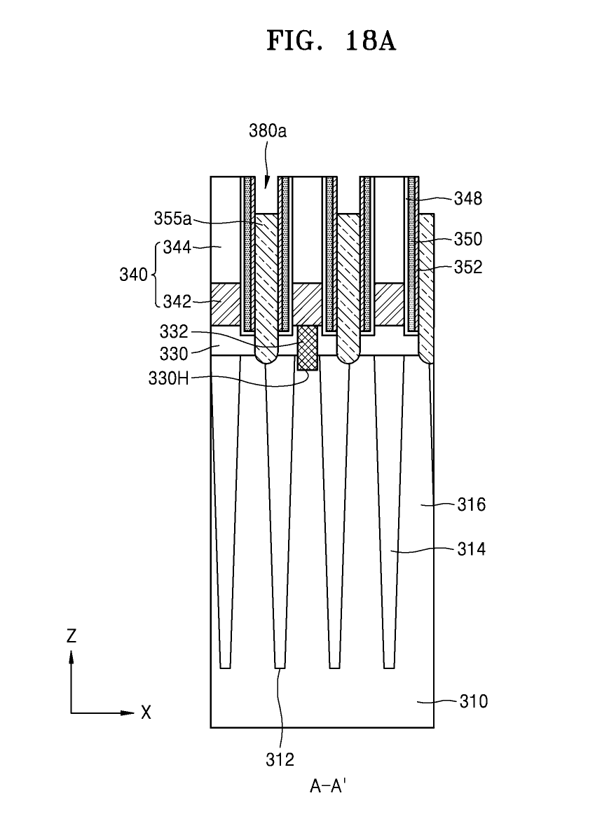

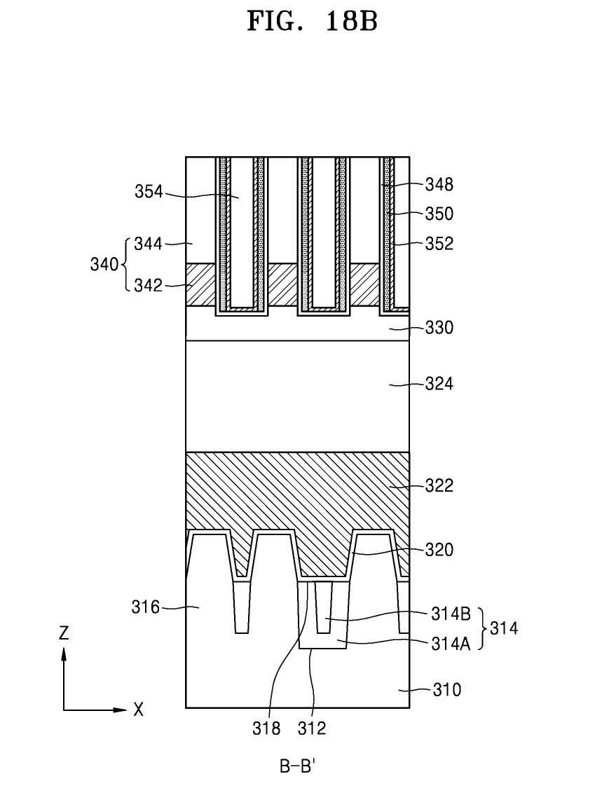

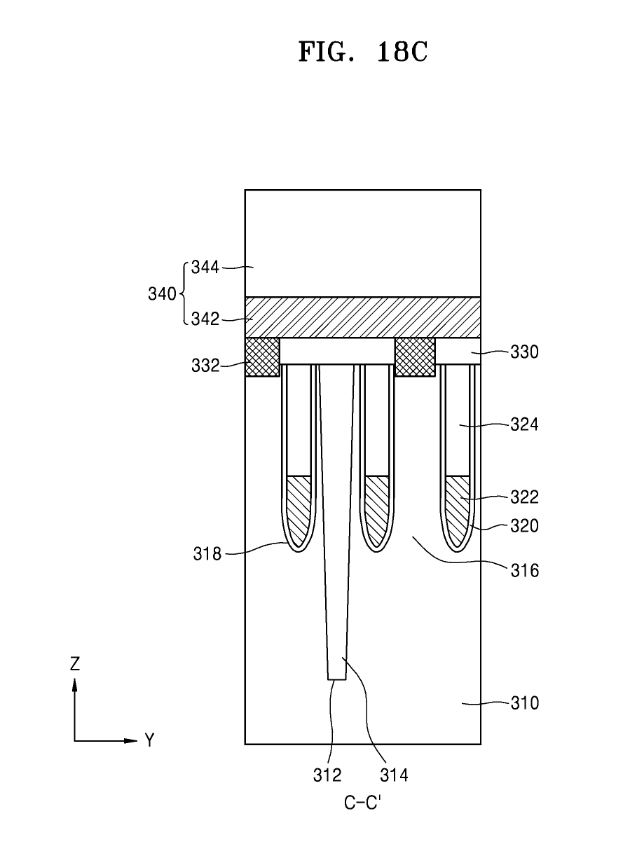

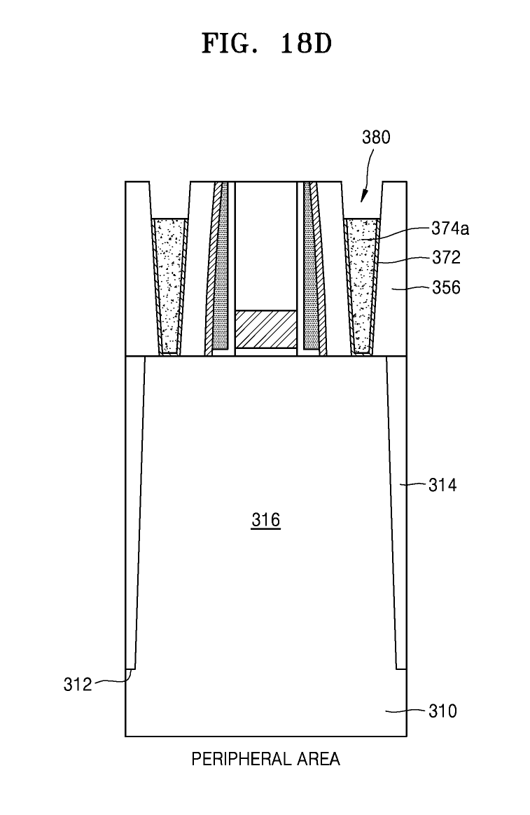

Referring to FIGS. 18a through 18d, the first barrier metal layer 372 and the contact plug material layer 374 may be planarized to expose an upper surface of the interlayer dielectric layer 356 by applying an etch-back process or a CMP process.

A plurality of recess regions 380 and 380a may be formed by etching the upper portion of the first barrier metal layer 372 and the contact plug material layer 374 by applying an etch-back process to form a contact plug 374a having an upper surface in the peripheral circuit region. As shown in FIG. 18a, the conductive material layer 355 formed in the cell array region may be recessed simultaneously and a buried contact plug 355a may be formed in the cell array region. The plurality of recess regions 380 and 380a may each have a sidewall and a bottom. In another example embodiment of the inventive concepts, the conductive material layer 355 formed in the cell array region may not be recessed by applying an hard mask pattern.

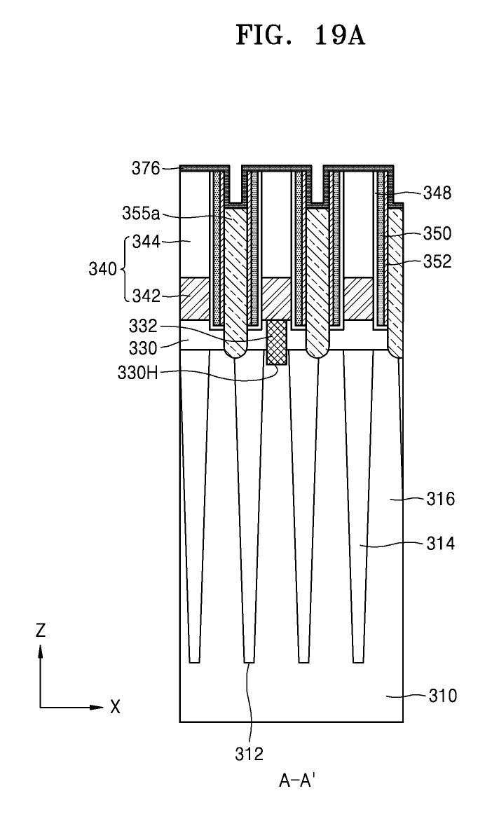

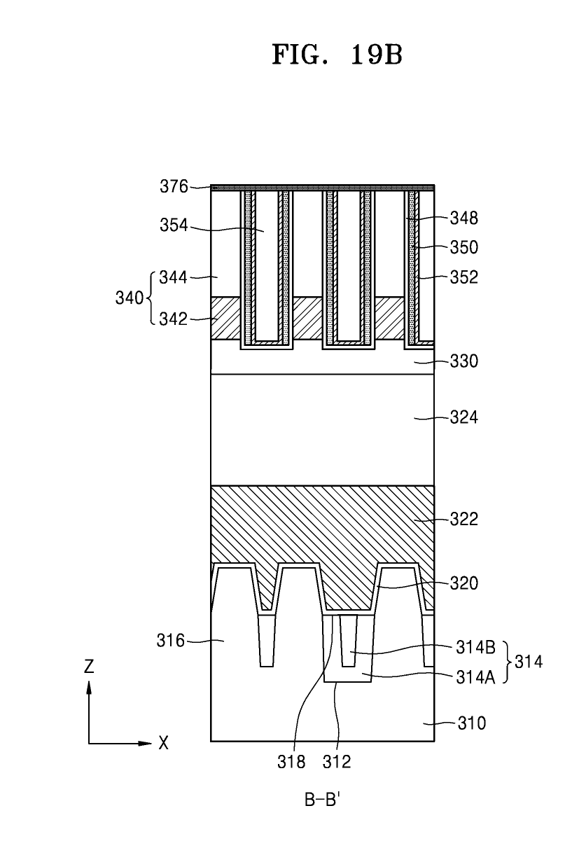

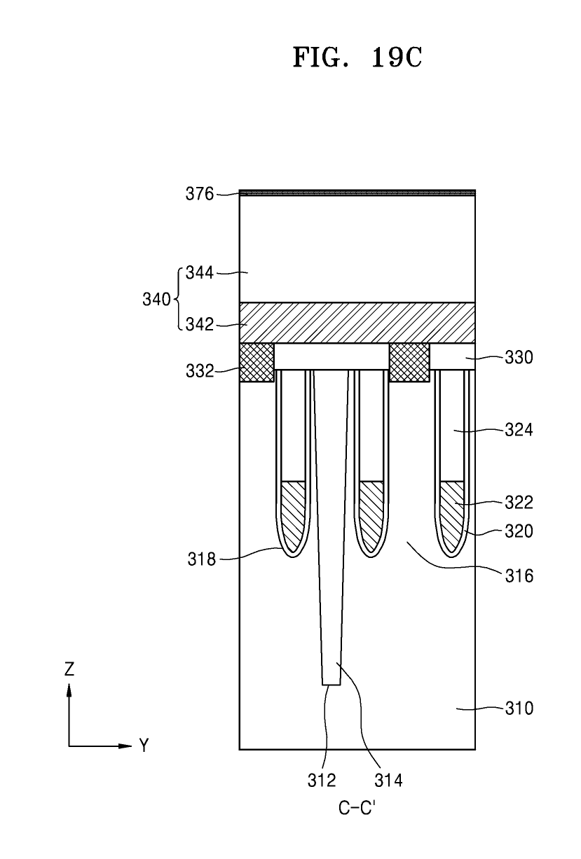

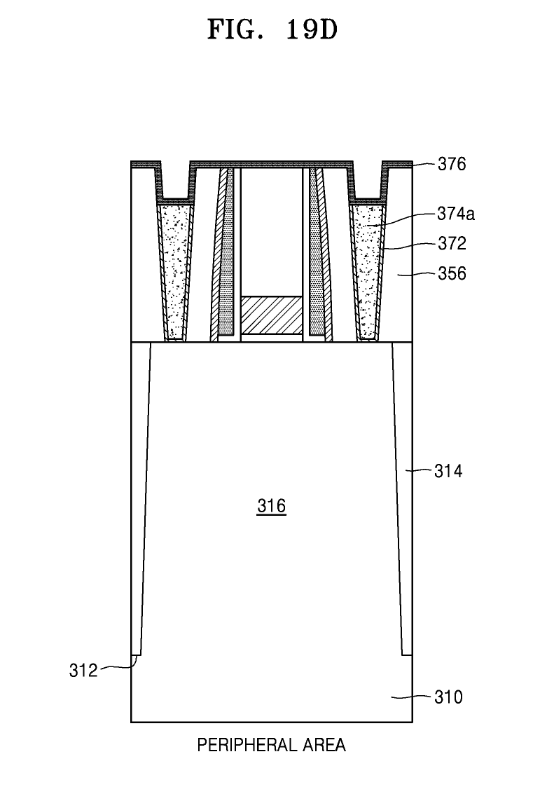

Referring to FIGS. 19a through 19d, a spacer material layer 376 may be formed on the sidewalls and the bottoms of the plurality of recess regions 380 and 380a. The spacer material layer 376 may be extended to at least partially be on the interlayer dielectric layer 356. The spacer material layer 376 may include silicon nitride, silicon oxynitride, and/or silicon oxide.

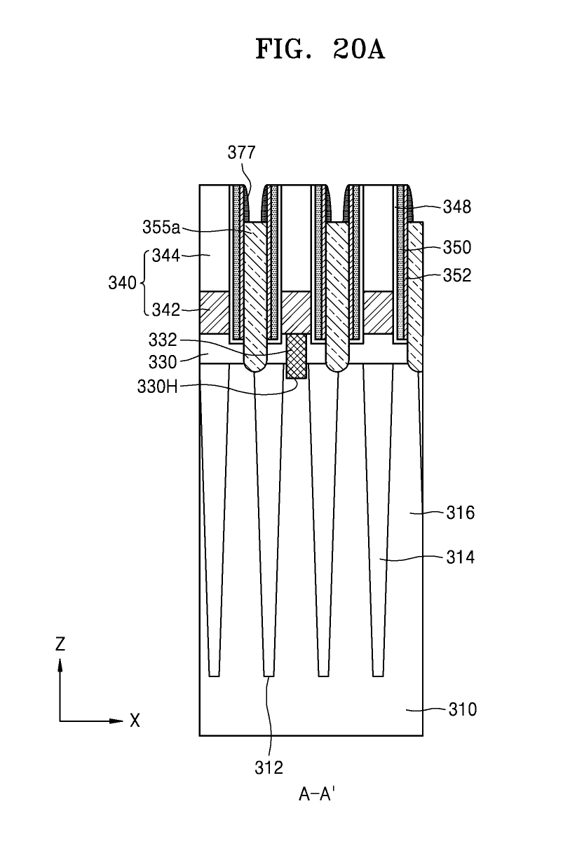

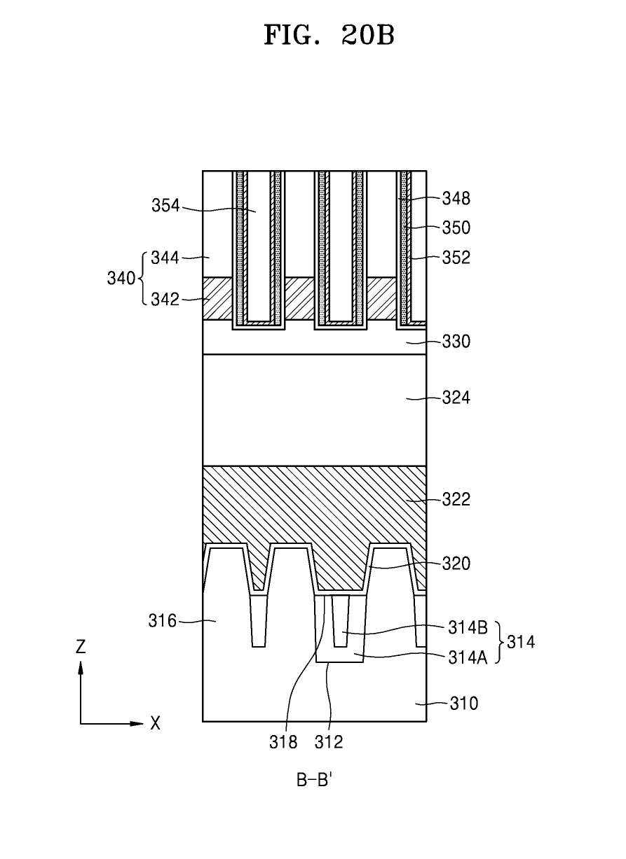

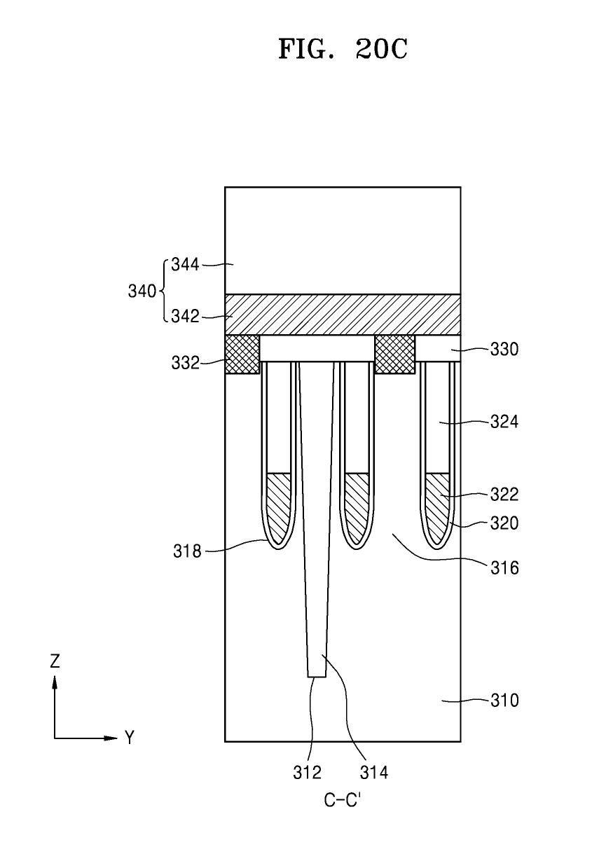

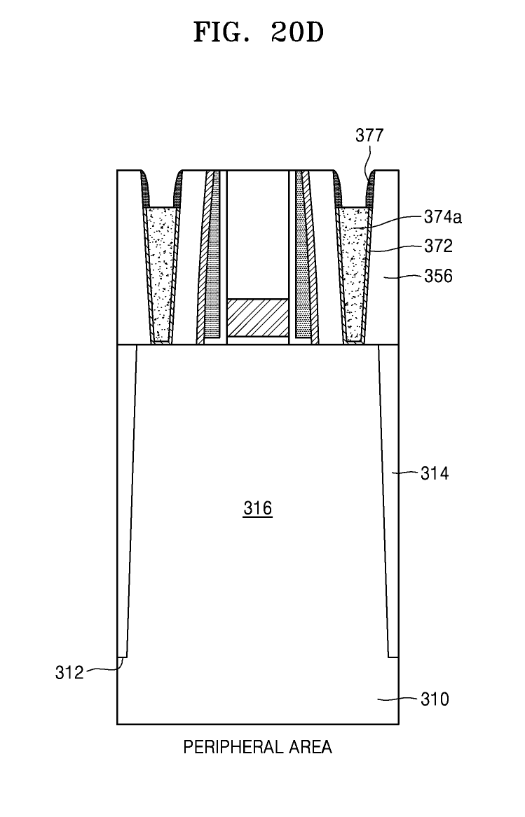

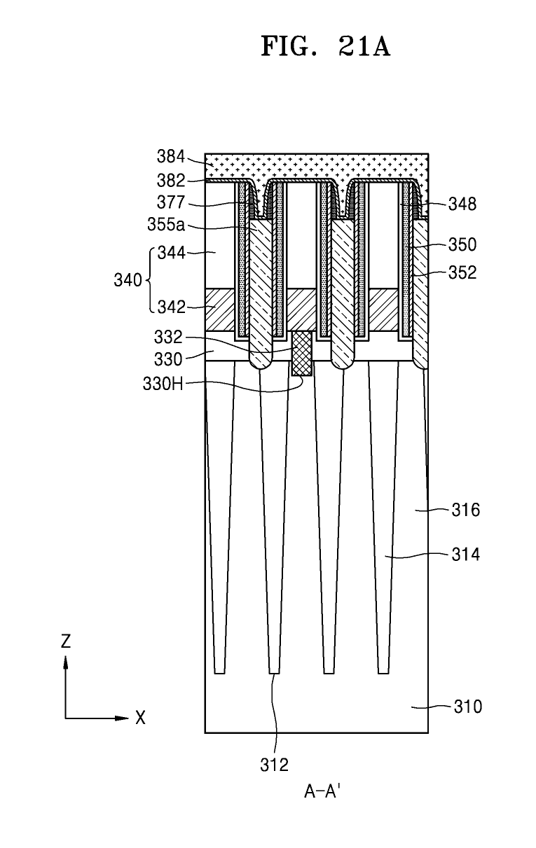

Referring to FIGS. 20a through 20d, a plurality of spacers 377 may be formed on the sidewalls of the plurality of recess regions 380 and 380a, respectively. The spacers 377 may be formed by etching the spacer material layer 376 to expose the upper surface of the contact plug 374a and the buried contact plug 355a using an etch-back process. A first width which is a width of the exposed upper surface of the contact plug 374a may be smaller than or equal to a second width which is a width of the bottom of the plurality of the contact holes 370.

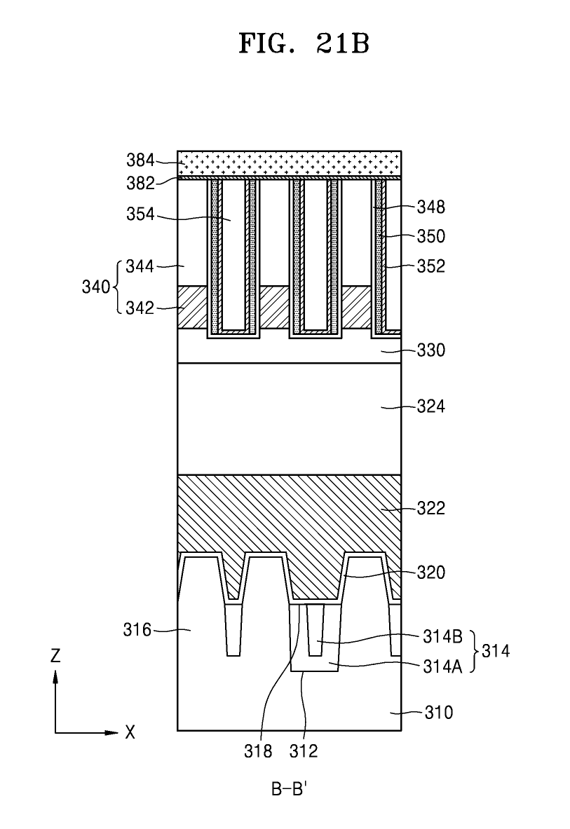

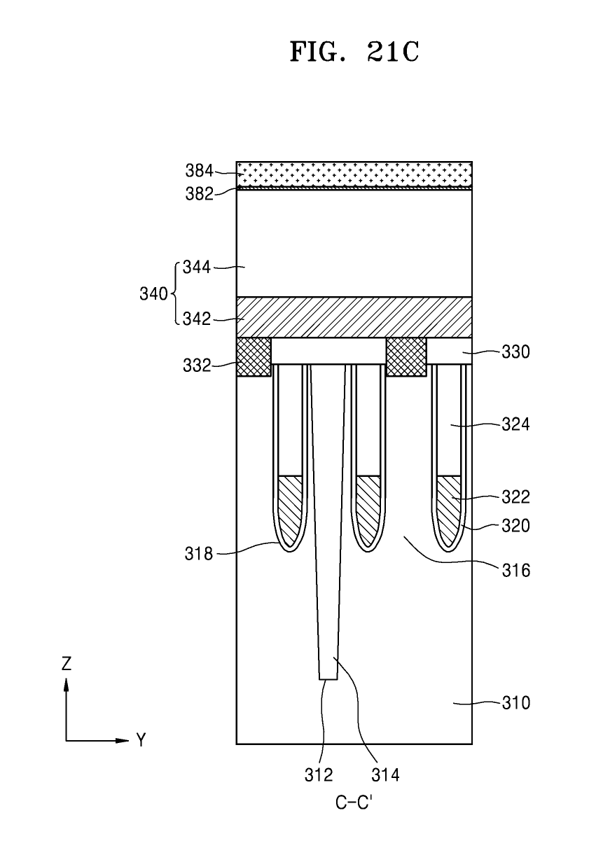

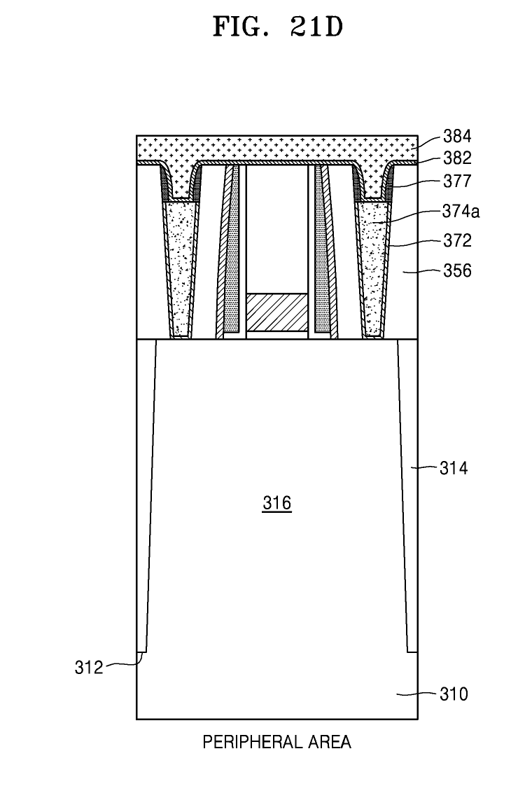

Referring to FIGS. 21a through 21d, a second barrier metal layer 382 and a conductive material layer 384 may be formed on the spacer 377, the contact plug 374a, and the buried contact plug 355a, respectively. The second barrier metal layer 382 may include titanium (Ti), titanium nitride (TiN), and/or titanium silicon nitride (TiSiN). The conductive material layer 384 may include doped polysilicon, tungsten, metal silicide, and/or conductive metal nitride.

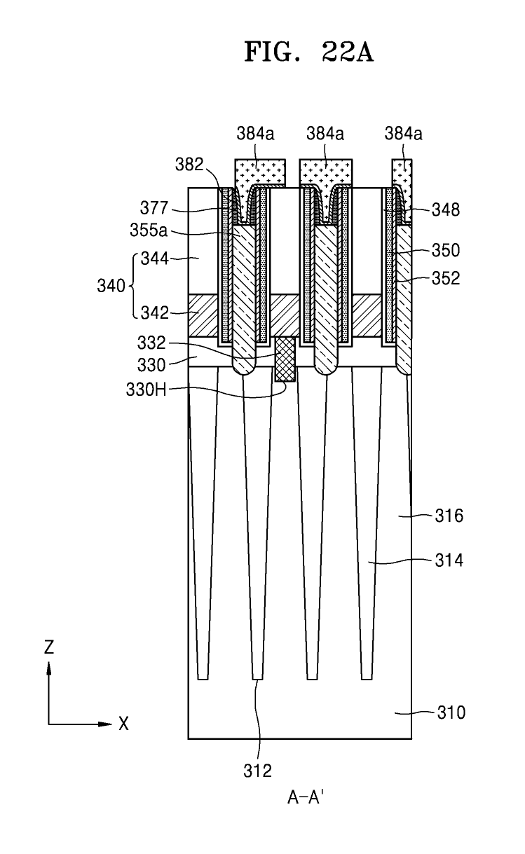

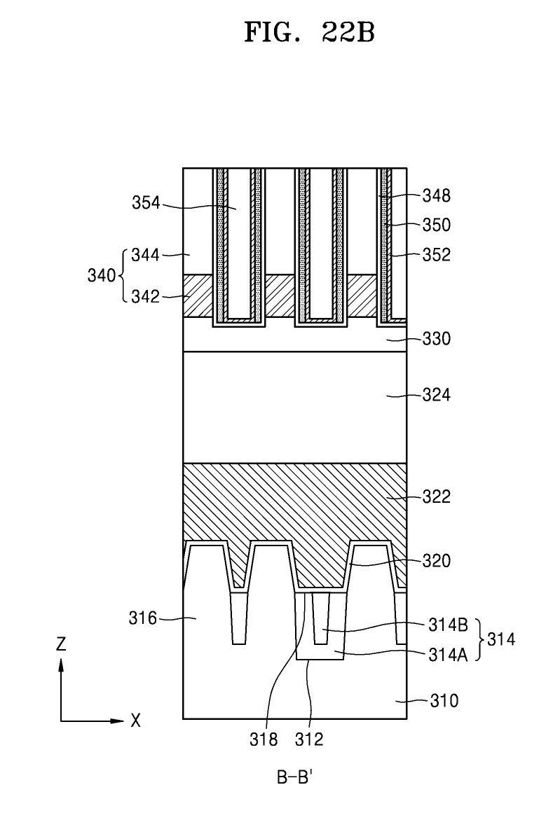

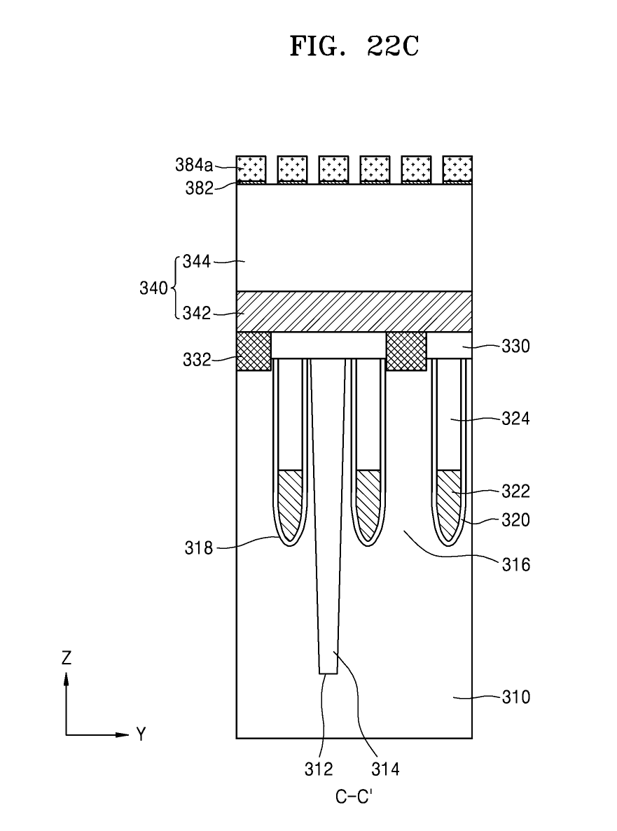

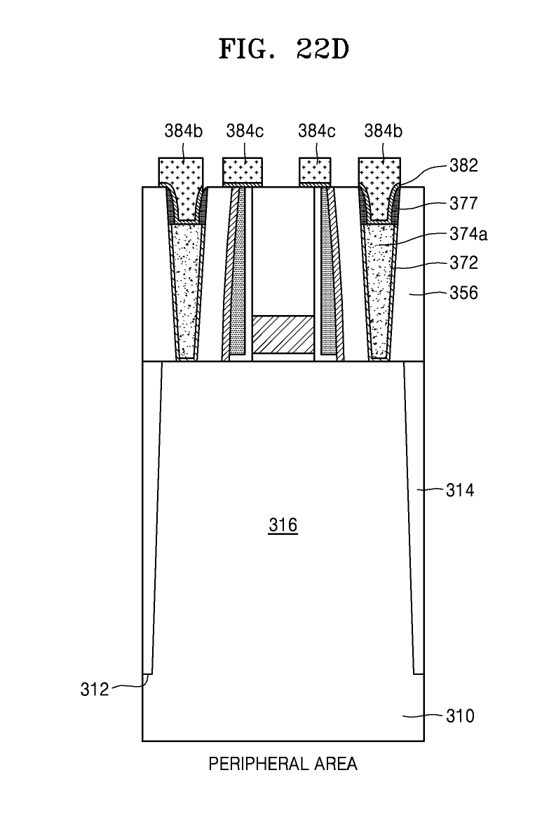

Referring to FIGS. 22a through 22d, conductive lines 384b and 384c may be formed by patterning the conductive material layer 384 and the second barrier metal layer 382 using a lithography process and a dry etching process. As shown in FIG. 22d, the conductive line 384b may be formed on the spacer 377, which in turn is positioned on the contact plug 374a. The conductive line 384c may be formed on the interlayer dielectric layer 356. A portion of the conductive line 384c may be extended to be positioned on the gate hard mask pattern 344.

In another example embodiment of the inventive concepts, as shown in FIG. 22a, the conductive material layer 384 may be patterned to form a plurality of conductive pads 384a. The conductive pads 384a may have an island shape or the like. The conductive pads 384a may be electrically connected to the buried contact plugs 355a and a lower electrode of a capacitor.

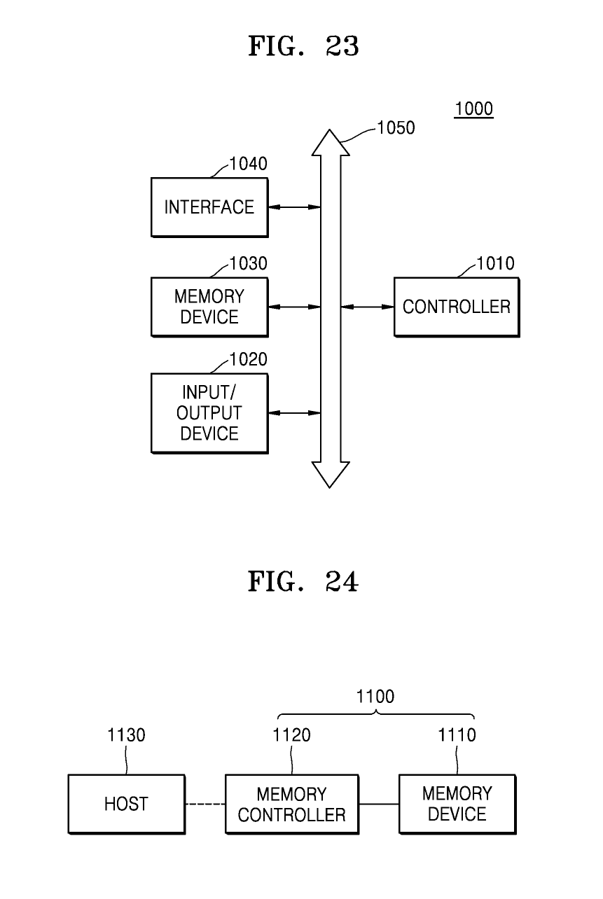

FIG. 23 is a diagram of a system 1000 according to an embodiment of the inventive concepts.

The system 1000 may comprise a controller 1010, an input/output device 1020, a memory device 1030, and an interface 1040. The system 1000 may be part of a mobile system or a product that can transport information, e.g., a navigation system, a solid state disk, or a household appliance. In embodiments where the system 1000 is part of a mobile system, the mobile system may comprise a PDA, a portable computer, a web tablet, a wireless phone, a mobile phone, a digital music player, or a memory card.

The controller 1010 may comprise but not be limited to a microprocessor, a digital signal processor, a microcontroller, or a similar device that can control an executive program.

The input/output device 1020 may comprise but not be limited to a keypad, a keyboard, and/or a display.

The memory device 1030 may not only save codes or data for executing the controller 1010 but also save data executed by the controller 1010. The memory device 1030 may comprise a FinFET (Fin-type Field Effect Transistor) manufactured according to an embodiment of the inventive concepts. For example, the memory device 1030 may comprise at least one semiconductor device disclosed in FIGS. 1 through 22d.

The system 1000 may transport data to an external device through the interface 1040. The controller 1010, the input/output device 1020, the memory device 1030, and the interface 1040 may communicate with each other through a bus 1050.

FIG. 24 is a block diagram comprising a memory card 1100 including a semiconductor device according to an embodiment of the inventive concepts. The memory card 1100 may comprise a memory device 1110 and a memory controller 1120. The memory device 1110 may include a DRAM or a FLASH device which is manufactured according to an example embodiment of the inventive concepts. The memory controller 1120 may read/save data from/to the memory device 1110 by requesting from a host 1130. The memory controller 1120 may include at least one semiconductor device, for example disclosed at least at FIGS. 1 through 22d.

The above-disclosed subject matter is to be considered illustrative and not restrictive, and the appended claims are intended to cover all such modifications, enhancements, and other embodiments, which fall within the true spirit and scope of the inventive concepts. Thus, to the maximum extent allowed by law, the scope of the inventive concepts is to be determined by the broadest permissible interpretation of the following claims and their equivalents, and shall not be restricted or limited by the foregoing detailed description.

1. A semiconductor device, comprising:
a substrate having a cell array region and a peripheral circuit region;
a gate electrode on the substrate;
an interlayer dielectric layer adjacent to the gate electrode on the substrate, the interlayer dielectric layer having an upper surface having a first height;
a contact hole extending through the interlayer dielectric layer to expose a portion of the substrate;
a contact plug having an upper surface and electrically communicating with the substrate in the contact hole, the upper surface of the contact plug having a center portion, edge portion, and a second height lower than the first height;
a spacer on the sidewall of the contact hole, the spacer directly abutting the edge portion of the upper surface of the contact plug; and
a first conductive line on the spacer and the center portion of the upper surface of the contact plug, the first conductive line electrically communicating with the contact plug.

2. The semiconductor device as claimed in claim 1, wherein the gate electrode is positioned at the peripheral circuit region.

3. The semiconductor device as claimed in claim 1, wherein the gate electrode includes at least one of tungsten (W), tungsten silicide (WSix), and titanium silicon nitride (TiSiN) or a combination thereof.

4. The semiconductor device as claimed in claim 1, further comprising:
a gate hard mask pattern on the gate electrode; and
a gate dielectric layer between the gate electrode and the substrate.

5. The semiconductor device as claimed in claim 4, further comprising a portion of a second conductive line positioned on the gate hard mask pattern.

6. The semiconductor device as claimed in claim 1, further comprising a second conductive line on the upper surface of the interlayer dielectric layer, the second conductive line adjacent to the first conductive line.

7. The semiconductor device as claimed in claim 6, wherein the first and second conductive lines are portions of bit lines.

8. The semiconductor device as claimed in claim 6, wherein the first and second conductive lines include tungsten (W).

9. The semiconductor device as claimed in claim 1, further comprising a first barrier metal layer between the contact plug and the substrate.

10. The semiconductor device as claimed in claim 9, wherein the first barrier metal layer includes at least one of titanium (Ti), titanium nitride (TiN), and titanium silicon nitride (TiSiN) or a combination thereof.

11. The semiconductor device as claimed in claim 1, further comprising a second barrier metal layer between the contact plug and the first conductive line.

12. The semiconductor device as claimed in claim 11, wherein the second barrier metal layer includes at least one of titanium (Ti), titanium nitride (TiN), and titanium silicon nitride (TiSiN) or a combination thereof.

13. The semiconductor device as claimed in claim 1, wherein the spacer includes at least one of silicon nitride (SiN), silicon oxynitride (SiON), and silicon dioxide (SiO₂) or a combination thereof.

14. The semiconductor device as claimed in claim 1, wherein the spacer has two portions, the two portions comprising:
a first portion adjacent to the upper surface of the interlayer dielectric layer, the first portion having a first width; and
a second portion physically contacting to the contact plug, the second portion having a second width smaller than the first width.

15. The semiconductor device as claimed in claim 1, wherein the center portion of the upper surface of the contact plug has a third width and the bottom of the contact hole has a fourth width greater than or equal to the third width.

16. A semiconductor device, comprising:
a substrate having a cell array region and a peripheral circuit region;
a plurality of bit lines disposed on the substrate in the cell array region;
a gate electrode having a sidewall on the substrate in the peripheral circuit region;
a gate spacer on the sidewall of the gate electrode;
an interlayer dielectric layer adjacent to the gate electrode on the substrate, the interlayer dielectric layer having an upper surface having a first height;
a contact hole extending through the interlayer dielectric layer to expose a portion of the substrate, the contact hole adjacent to the gate spacer;
a contact plug having an upper surface and electrically communicating with the substrate in the contact hole, the upper surface of the contact plug having a center portion, an edge portion, and a second height lower than the first height;
a spacer on the sidewall of the contact hole, the spacer directly abutting the edge portion of the upper surface of the contact plug;
a first conductive line on the spacer and the center portion of the upper surface of the contact plug, the first conductive line electrically communicating with the contact plug; and
a second conductive line on the upper surface of the interlayer dielectric layer, the second conductive line adjacent to the first conductive line.

17. A method of manufacturing a semiconductor device, the method comprising:
providing a substrate having a cell array region and a peripheral circuit region;
forming a gate electrode on the substrate;
forming an interlayer dielectric layer adjacent to the gate electrode on the substrate, the interlayer dielectric layer having an upper surface having a first height;
forming a contact hole extending through the interlayer dielectric layer to expose a portion of the substrate;
forming a contact plug having an upper surface and electrically communicating with the substrate in the contact hole, the upper surface of the contact plug having a second height lower than the first height;
forming a spacer on the sidewall of the contact hole, the spacer directly abutting the edge portion of the upper surface of the contact plug;
forming a first conductive line on the spacer and the center portion of the upper surface of the contact plug, the first conductive line electrically communicating with the contact plug; and
forming a second conductive line on the upper surface of the interlayer dielectric layer, the second conductive line adjacent to the first conductive line.

18. The method as claimed in claim 17, wherein the gate electrode is formed in the peripheral circuit region.

19. The method as claimed in claim 17, wherein the spacer has two portions, the two portions comprising:
a first portion adjacent to the upper surface of the interlayer dielectric layer, the first portion having a first width; and
a second portion directly abutting the contact plug, the second portion having a second width smaller than the first width.

20. (canceled)
